(19) United States
(12) Patent Application Publication
(10) Pub. No.: US 2009/0269490 A1
(43) Pub. Date: Oct. 29, 2009

(54) COATING APPARATUS AND COATING METHOD

(76) Inventors: Yoshikazu MORIYAMA, Shizuoka (JP); Hideaki NISHIKAWA, Shizuoka (JP); Masayoshi YAJIMA, Kanagawa (JP); Hiroshi FURUTANI, Shizuoka (JP); Shinichi MITANI, Shizuoka (JP); Michio NISHIBAYASHI, Shizuoka (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/425,148

(22) Filed: Apr. 16, 2009

(30) Foreign Application Priority Data
Apr. 25, 2008 (JP) 2008-115037
Feb. 25, 2009 (JP) 2009-042180

(51) Int. Cl. C23C 16/44; B05C 11/00; B05D 3/12

(52) U.S. Cl. 427/240; 118/725; 118/708

(57) ABSTRACT

An object of the present invention is to provide a coating apparatus in which the substrate can be reliably rotated at high speed. Another object of the invention is to provide a coating method of forming a coating on a substrate while reliably rotating it at high speed. A coating apparatus includes a susceptor for supporting a silicon wafer, and a rotating portion for rotating the susceptor. The rotating portion is covered on top with the susceptor to form a P₂ region. The contact surface of the susceptor with the silicon wafer has a plurality of holes therein. The silicon wafer is attached to the susceptor by evacuating gas from the P₂ region.

### BACKGROUND OF THE INVENTION

1. Field of the Invention

The present invention relates to a coating apparatus and a coating method.

2. Background Art

Epitaxial growth techniques are conventionally used to manufacture semiconductor devices requiring a relatively thick crystalline coating or film, such as power devices, including IGBTs (Insulated Gate Bipolar Transistors).

In order to produce an epitaxial wafer having a considerable coating thickness with high yield, it is necessary to bring new material gases one after another into contact with the uniformly heated surface of the wafer and thereby increase the coating speed. To do this, it is common practice that the wafer is subjected to epitaxial growth while it is rotated at high speed (see, e.g., Patent Document 1 below).

According to Patent Document 1, the susceptor supporting the wafer thereon is fitted into a susceptor support, and the rotational shaft coupled to the susceptor support is rotated to rotate the wafer. However, since the wafer is placed on the susceptor without any securing means, it might come out of alignment with the susceptor at high rotational speeds.

The pressure in the coating chamber is adjusted to a predetermined level when the epitaxial growth is conducted. However, if the pressure inside the susceptor support, which is substantially sealed with the susceptor and the wafer, exceeds the pressure in the coating chamber, then the wafer might be displaced out of alignment with the susceptor.

Further, the wafer is heated by application of heat to its back surface when an epitaxial coating is formed on the top surface of the wafer. At that time, the wafer is warped concavely due to the heat so that its outer edge portion curves away from the susceptor surface. As a result, the wafer might be likely to come out of alignment with the susceptor at high rotational speeds.

### [Patent Document 1]

Japanese Laid-Open Patent Publication No. 5-152207 (1993)

### SUMMARY OF THE INVENTION

If the wafer comes out of alignment with the susceptor due to the cause described above, a coating cannot be formed on the wafer, resulting in a significant reduction in the manufacturing yield of the epitaxial wafer. Therefore, there is an urgent need for a technique whereby the wafer is prevented from being displaced out of alignment with the susceptor.

The present invention has been made in view of the above problems It is, therefore, an object of the present invention to provide a coating apparatus in which the substrate can be reliably rotated at high speed.

Another object of the present invention is to provide a coating method of forming a coating on a substrate while reliably rotating it at high speed.

According to one aspect of the present invention, a coating apparatus for forming a coating on a substrate which has been introduced into a coating chamber, the coating apparatus comprises a support portion for supporting the substrate, a rotating portion for rotating the support portion, the rotating portion being covered on top with the support portion to form a hollow region, a heating unit disposed in the hollow region to heat the substrate through the support portion, and evacuating means for evacuating gas from the hollow region. The contact surface of the support portion with the substrate has a plurality of holes therein. The substrate is attached to the support portion by evacuating the gas from the hollow region.

According to another aspect of the present invention, in a method of forming a coating on a substrate placed in a coating chamber, the substrate is introduced into the coating chamber, and the substrate is placed on a support portion having a plurality of holes in a surface thereof. The substrate is heated while rotating the substrate through the support portion. After the substrate has reached a predetermined temperature, the substrate is attached to the support portion by evacuating gas from a space substantially isolated from said coating chamber by said support portion.

Other objects and advantages of the present invention will become apparent from the following description.

### BRIEF DESCRIPTION OF THE DRAWINGS

FIG. 1 is a cross-sectional view of a coating apparatus according to an embodiment of the present invention.

FIG. 2 is a cross-sectional view of a susceptor with a wafer mounted thereon according to the embodiment.

FIG. 3 is a top view of the susceptor according to the embodiment

FIG. 4 is an enlarged cross-sectional view of a portion of the susceptor according to the embodiment.

FIG. 5 is a flowchart illustrating a coating method of the embodiment.

FIG. 6 includes graphs showing the relationships between the elapsed time during the coating process and the surface temperature and the speed of rotation of the wafer according to the embodiment.

FIG. 7 is a cross-sectional view illustrating the way in which the silicon wafer is attached to the susceptor by suction according to the embodiment.

FIG. 8 is a diagram showing examples of curves representing the frictional force between the silicon wafer and the susceptor as a function of the difference in pressure between the P₁ region and the P2 region in the coating apparatus according to the embodiment.

FIG. 9 is a diagram showing examples of curves representing the centrifugal force acting on the silicon wafer as a function of its speed of rotation according to the embodiment.

### DETAILED DESCRIPTION OF THE PREFERRED EMBODIMENTS

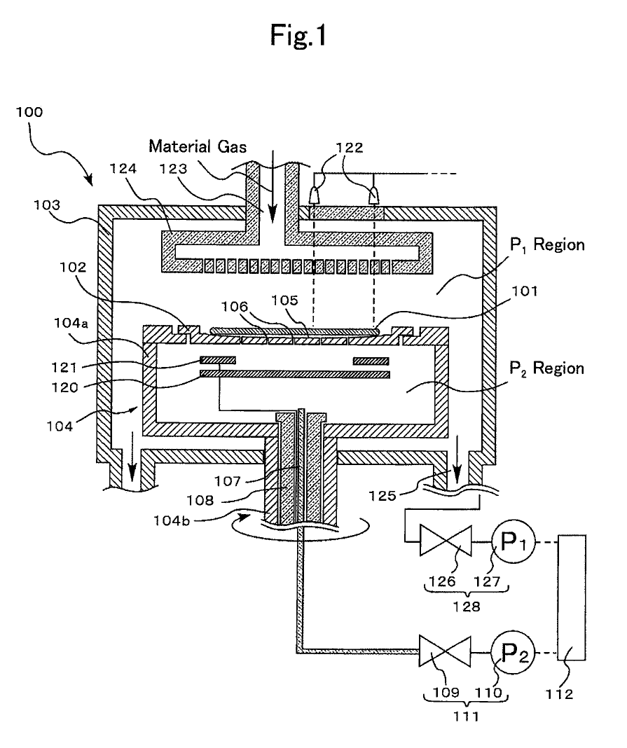

FIG. 1 is a schematic cross-sectional view of a coating apparatus 100 of a single wafer processing type according to an embodiment of the present invention. The substrate of the present embodiment described herein is a silicon wafer 101. However, the embodiment is not limited to this particular substrate, but may be applied to wafers of other suitable material depending on the application intended.

The coating apparatus 100 includes a chamber 103 serving as a coating chamber.

A gas supply portion 123 is provided above the chamber 103 to supply a material gas to the surface of the silicon wafer 101 in a heated state to form a crystalline coating on the surface. The gas supply portion 123 has connected thereto a shower plate 124 having a large number of material gas discharge holes formed therein. The shower plate 124 is disposed to face the surface of the silicon wafer 101 to supply material gas thereto.

A plurality of gas exhaust portions 125 are provided at the bottom of the chamber 103 to exhaust material gas from the chamber 103 after the gas is subjected to reaction. The gas exhaust portions 125 are coupled to an evacuating mechanism 128 made up of a regulating valve 126 and a vacuum pump 127. The evacuating mechanism 128 adjusts the pressure in the chamber 103 to a predetermined level under the control of a control mechanism 112.

In the chamber 103, a susceptor 102 serving as a support portion is disposed on a rotating portion 104.

The rotating portion 104 includes a cylindrical portion 104a and a rotating shaft 104b. The rotating shaft 104b is rotated by a motor, not shown, to rotate the susceptor 102 through the cylindrical portion 104a.

Referring to FIG. 1, the cylindrical portion 104a is open at its top but covered on top with the susceptor 102, thereby forming a hollow region (hereinafter referred to as the “P₂ region”). The space inside of the chamber 103 is referred to herein as the “P₁ region.” The P₂ region is substantially isolated from the P₁ region by the susceptor 102.

An inner heater 120 and an outer heater 121 are provided in the P₂ region to heat the silicon wafer 101 by application of heat to its back surface through the susceptor 102. A radiation thermometer 122 mounted at the top of the chamber 103 is used to measure the surface temperature of the silicon wafer 101, which temperature varies in response to the heat applied to the wafer. It should be noted that the shower plate 124 may be of transparent quartz so as not to interfere with the temperature measurement by the radiation thermometer 122. The measured temperature data is sent to a control mechanism, not shown, and then fed back to control the output of the inner and outer heaters 120 and 121. This allows the silicon wafer 101 to be heated such that the temperature distribution is uniform across its surface.

The rotating shaft 104b of the rotating portion 104 extends out of the chamber 103 and is coupled to a rotating mechanism, not shown, and rotated about its center line perpendicular to the silicon wafer 101 at a predetermined speed. This rotates the susceptor 102 and hence the silicon wafer 101 mounted thereon.

The rotating portion 104 includes an exhaust pipe 107 serving as exhaust means for exhausting gas from the P₂ region. The exhaust pipe 107 passes through a substantially cylindrical quartz shaft 108 in the rotating shaft 104b and is connected to an evacuating mechanism 111 made up of a regulating valve 109 and a vacuum pump 110 provided outside the chamber 103.

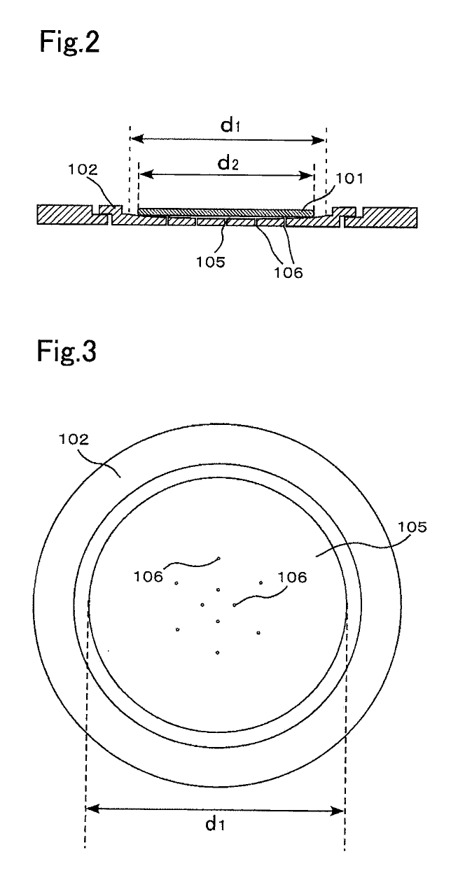

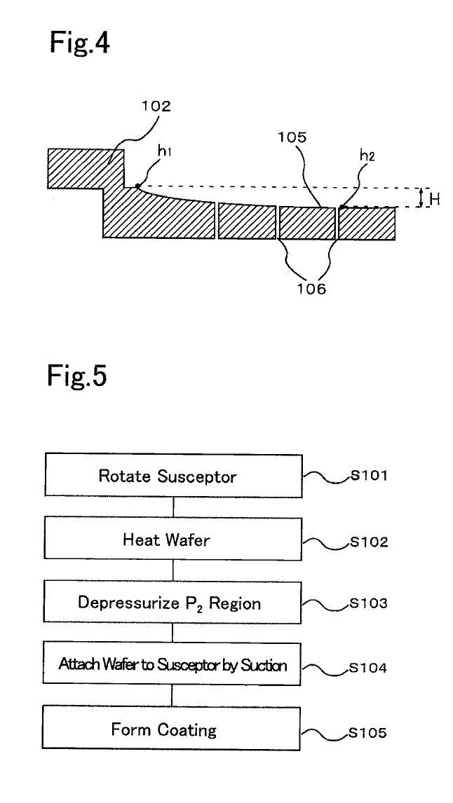

FIG. 2 is a cross-sectional view of the susceptor 102 with the silicon wafer 101 mounted thereon. FIG. 3 is a top view of the susceptor 102. Further, FIG. 4 is an enlarged cross-sectional view of a portion of the susceptor 102.

As shown in FIGS. 2 to 4, the contact surface 105 of the susceptor 102 in contact with the silicon wafer 101 has formed therein a plurality of holes 106 that extend through the susceptor 102 and communicate between the P₁ region and the P₂ region. In operation, the evacuating mechanism 111 evacuates gas from the P₂ region, with the result that the pressure in the P₂ region is lower than that in the P₁ region. As a result of this pressure difference, the silicon wafer 101 is drawn toward the P₂ region by the suction through the holes 16, causing the silicon wafer 101 to be attached to the susceptor 102. This allows the silicon wafer 101 to be reliably held in place on the susceptor 102 even when the susceptor 102 is rotated at high speed. It should be noted that the evacuating mechanism 111 may be connected to the control mechanism 112, which controls the pressure in the P₁ region, in order to vary the pressure in the P₂ region in accordance with the pressure in the P₁ region.

Although in FIG. 3 the holes 106 are shown to be arranged primarily near the center portion of the contact surface 105, it is to be understood that they may be distributed over the entire contact surface 105 at equal intervals, or they maybe concentrically arranged around the center of the contact surface 105. If the diameter or the number of these holes 106 is too large, the inside of the chamber 103 might be contaminated with metals originating from various members in the rotating portion 104. Therefore, the size and number of these holes are determined such that the silicon wafer 101 can be attached to the susceptor 102 by suction while avoiding this problem.

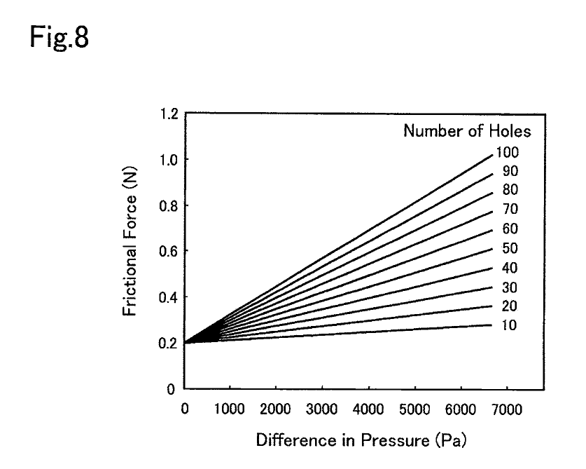

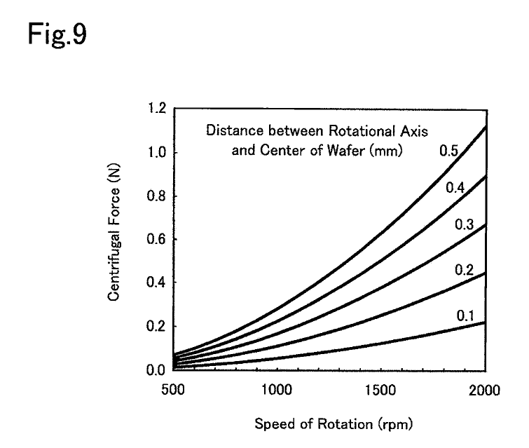

FIG. 8 is a diagram showing examples of curves representing the frictional force between the silicon wafer 101 and the susceptor 102 as a function of the difference in pressure between the P₁ and P₂ regions. In this case, the holes 106 in the susceptor 102 are 2 mm in diameter. For a given pressure difference, the more holes 106, the higher the frictional force, as can be seen from FIG. 8. Further, for a given number of holes 106, the larger the pressure difference, the higher the frictional force. This tendency (i.e., the rate of increase of the frictional force with respect to the rate of increase of the pressure difference) increases with the number of holes 106. FIG. 9 is a diagram showing examples of curves representing the centrifugal force acting on the silicon wafer 101 as a function of its speed of rotation. For a given speed of rotation, the larger the distance between the rotational axis of the rotating portion 104 and the center of the silicon wafer 101, the higher the centrifugal force, as can be seen from FIG. 9. Further, for a given distance between the rotational axis of the rotating portion 104 and the center of the silicon wafer 101, the higher the speed of rotation, the higher the centrifugal force. This tendency (i.e., the rate of increase of the centrifugal force with respect to the rate of increase of the speed of rotation) increases with the distance between the rotational axis of the rotating portion 104 and the center of the silicon wafer 101. According to the present embodiment, with reference to FIGS. 8 and 9, the difference in pressure between the P₁ and P₂ regions and the number of holes 16 are set such that the frictional force>the centrifugal force.

The contact surface 105 is preferably concavely curved, as shown in FIGS. 2 and 4, that is, it is preferably inclined from its outer edge portion downward toward its center portion. The reason for this is that the silicon wafer 101 is warped by the heat applied thereto when a coating is formed thereon. That is, the contact surface 105 is designed to have a shape matching the shape of the silicon wafer 101 when the wafer is heated. This prevents the silicon wafer 101 from being floated from the susceptor 102 and thereby brought out of alignment with the susceptor 102 when a coating is formed on the silicon wafer 101. For example, when the silicon wafer 101 is an 8 inch wafer (having a diameter of approximately 200 mm), the difference in height H between the substantially horizontal surface h₁ of the outer edge portion of the susceptor 102 and the surface h₂ of the lowest center portion is preferably in a range of 2-30 μm. This ensures that the contact surface 105 is fully in contact with the back surface of the silicon wafer 101 when the wafer is warped as a result of the heating.

Referring to FIG. 3, the diameter d₁ of the substantially circular contact surface 105 is preferably equal to or greater than the diameter d₂ of the silicon wafer 101 mounted thereon. When d₁≧d₂, even the outer edge portion of the silicon wafer 101 can be brought into contact with the contact surface 105, thereby increasing the adhesion of the silicon wafer 101 to the susceptor 102.

If the diameter of the silicon wafer 101 is changed, then the depth H and the diameter d₁ of the contact surface 105 are preferably changed accordingly.

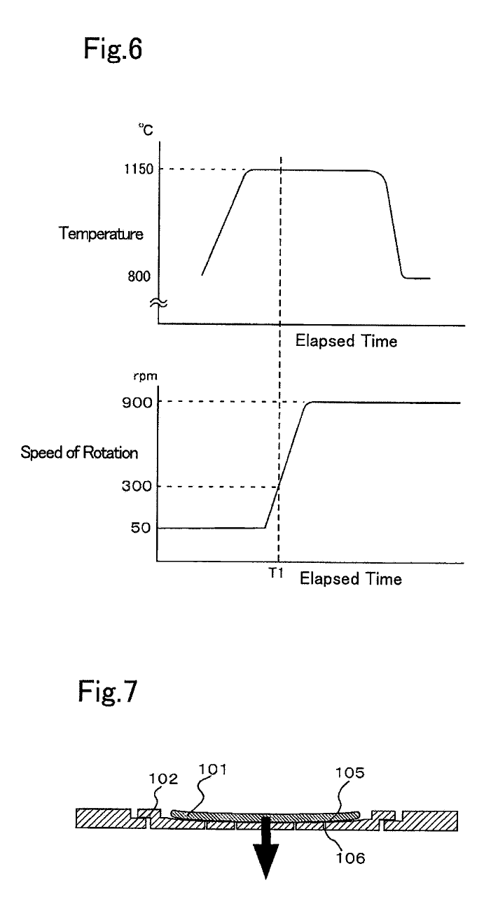

FIG. 5 is a flowchart illustrating a coating method of the present embodiment. FIG. 6 includes graphs showing the relationships between the elapsed time during the coating process and the surface temperature and the speed of rotation of the silicon wafer 101. Further, FIG. 7 is an enlarged cross-sectional view illustrating the way in which the silicon wafer 101 is attached to the susceptor 102 by suction in the coating process of the present embodiment.

The coating method of one aspect of the present embodiment includes the following steps.

First, the silicon wafer 101 is placed on the susceptor 102, as shown in FIG. 2, and the rotating portion 104 is rotated to rotate the silicon wafer 101 at a speed of approximately 50 rpm (step S101).

The silicon wafer 101 is then heated by the inner heater 120 and the outer heater 121. More specifically, for example, the wafer is gradually heated to a coating temperature of 1150° C. (S102).

After the temperature of the silicon wafer 101 reaches 1150° C. as measured by the radiation thermometer 122, the speed of rotation of the silicon wafer 101 is gradually increased. When the speed of rotation of the silicon wafer 101 has exceeded 300 rpm (T1), the evacuating mechanism 111 is operated to begin to reduce the pressure in the P₂ region (S103). Then, material gas is delivered from the gas supply portion 123 to the surface of the silicon wafer 101 through the shower plate 124.

When the pressure in the P region becomes lower than the pressure in the P₁ region, a downward force is exerted on the silicon wafer 101, as indicated by the arrow in FIG. 7. This causes the silicon wafer 101 to be attached to the susceptor 102 (S104).

The silicon wafer 101 begins to warp and become downwardly convex when maintained at a temperature of approximately 1150° C. At that time, the silicon wafer 101 can be closely attached to the susceptor 102, since the contact surface 105 of the susceptor 102 is concavely curved, i.e., inclined from its outer edge portion downward toward its center portion. This allows the silicon wafer 101 to be reliably held in place even when the susceptor 102 is rotated, e.g., at 900 rpm or more, thus preventing the silicon wafer 101 from coming out of alignment with the susceptor 102.

The control mechanism 112 preferably controls the evacuating mechanism 111 such that the pressure in the P₂ region is reduced to 90% or more of the pressure in the P₁ region. For example, when the pressure in the P₁ region is 700 Torr, the P₂ region is depressurized to approximately 630 Torr or more. This allows the silicon wafer 101 to be attached to the susceptor 102 by sufficient suction force without exerting excessive force on the wafer. Furthermore, the disturbance of the material gas flow in the P₁ region can be minimized.

Under the above conditions new material gases are delivered, one after another, through the shower plate 124 to the silicon wafer 101 from the gas supply portion 123 provided at the top of the chamber 103 to efficiently form an epitaxial coating at a high rate (S105).

Thus, the coating apparatus and coating method of the present embodiment allow a substrate to be reliably rotated even when the susceptor is rotated at high speed to increase the coating speed, thus making it possible to produce an epitaxial wafer with high manufacturing yield.

The present embodiment has been described with reference to specific examples. It is to be understood, however, that the present invention is not limited to this particular embodiment, since various alterations may be made without departing from the spirit and scope of the invention.

For example, according to the one aspect of the present embodiment described above, the P₂ region begins to be depressurized when the speed of rotation of the susceptor 102 has exceeded approximately 300 rpm. The reason for this is that the material gas flow over the silicon wafer 101 becomes laminar when the speed of rotation of the susceptor 102 is approximately 300 rpm, meaning that at this susceptor speed the material gas flow is not disturbed even if the P₂ region is depressurized. However, the process conditions such as the pressure and temperature in the chamber 103 may be changed to cause the material gas flow over the silicon waver 101 to become laminar at a different susceptor speed. In this way, the timing of depressurizing the P₂ region can be changed from that described above. That is, the P₂ region may be depressurized when it is ensured that the flow of the material gas delivered to the silicon wafer 101 is not disturbed.

Although the coating apparatus of the present invention has been described with reference to an epitaxial growth apparatus, it is to be understood that the invention is not limited to this particular apparatus, but can be applied to any apparatus for forming a prescribed crystal coating on the surface of a silicon wafer by vapor phase epitaxy. For example, the present invention may be applied to coating apparatus for growing a polysilicon film, resulting in the same operating advantages as described above in connection with the invention.

The above description of the present invention has not specified apparatus constructions, control methods, etc. which are not essential to the invention, since any suitable apparatus constructions, control methods, etc. can be employed to implement the invention.

The figures used to describe the present invention do not show components which are not essential in describing the invention. Further, these figures are not drawn to scale, and certain features and dimensions are shown in modified or exaggerated form for clarity when appropriate.

The scope of this invention encompasses all vapor phase growth apparatuses embodying the elements of the invention and variations thereof which can be designed by those skilled in the art, and also encompasses the configurations of the components of these apparatuses.

The features and advantages of the present invention may be summarized as follows.

In the coating apparatus of the first aspect of the present invention, the contact surface of the support portion with the substrate has a plurality of holes therein, and the substrate is attached to the support portion by evacuating gas from the hollow region. This arrangement allows the substrate to be reliably rotated at high speed.

According to the coating method of the second aspect of the present invention, after the substrate has reached a predetermined temperature, it is attached to the support portion by evacuating gas from a space substantially isolated from the coating chamber by the support portion. This arrangement allows forming a coating on the substrate while reliably rotating the substrate at high speed.

Obviously many modifications and variations of the present invention are possible in the light of the above teachings. It is therefore to be understood that within the scope of the appended claims the invention may be practiced otherwise than as specifically described.

The entire disclosure of a Japanese Patent Applications No. 2008-115037, filed on Apr. 25, 2008 and No. 2009-042180, filed on Feb. 25, 2009 including specifications, claims, drawings and summarys, on which the Convention priority of the present application is based, are incorporated herein by reference in its entirety.

What is claimed is:

1. A coating apparatus for forming a coating on a substrate which has been introduced into a coating chamber, said coating apparatus comprising:
a support portion for supporting said substrate;
a rotating portion for rotating said support portion, said rotating portion being covered on top with said support portion to form a hollow region;
a heating unit disposed in said hollow region to heat said substrate through said support portion; and
evacuating means for evacuating gas from said hollow region;
wherein the contact surface of said support portion with said substrate has a plurality of holes therein; and
wherein said substrate is attached to said support portion by evacuating said gas from said hollow region.

2. The coating apparatus as claimed in claim 1, wherein said contact surface of said support portion with said substrate is concavely curved such that said contact surface is inclined from an outer edge portion thereof toward a center portion thereof.

3. The coating apparatus as claimed in claim 1, wherein said evacuating means is connected to control means for controlling the pressure in said coating chamber.

4. The coating apparatus as claimed in claim 1, wherein the number of said holes and the difference between the pressure in said coating chamber and the pressure in said hollow region are such that the frictional force between said support portion and said substrate is greater than the centrifugal force acting on said substrate.

5. The coating apparatus as claimed in claim 1, wherein the diameter of said support portion is equal to or greater than the diameter of said substrate.

6. A method of forming a coating on a substrate placed in a coating chamber, said method comprising the steps of:
introducing said substrate into said coating chamber and placing said substrate on a support portion having a plurality of holes in a surface thereof;
heating said substrate while rotating said substrate through said support portion; and
after said substrate has reached a predetermined temperature, attaching said substrate to said support portion by evacuating gas from a space substantially isolated from said coating chamber by said support portion.

7. The method as claimed in claim 6, wherein said predetermined temperature is a coating temperature.

8. The method as claimed in claim 6, wherein said step of attaching said substrate to said support portion includes reducing the pressure in said space to 90% or more of the pressure in said coating chamber.

9. The method as claimed in claim 6, further comprising the step of:
supplying material gas to a surface of said substrate;
wherein said step of attaching said substrate to said support portion is performed after said substrate has reached said predetermined temperature and after said substrate has reached a speed of rotation at which said material gas flows in a laminar state.

10. The method as claimed in claim 6, wherein the pressure in said space substantially isolated from said coating chamber by said support portion is varied in accordance with the pressure in said coating chamber.

11. The method as claimed in claim 6, wherein the number of said holes and the difference between the pressure in said coating chamber and the pressure in said space substantially isolated from said coating chamber by said support portion are such that the frictional force between said support portion and said substrate is greater than the centrifugal force acting on said substrate.

12. The method as claimed in claim 6, wherein the diameter of said support portion is equal to or greater than the diameter of said substrate.
